(19) United States
(12) Patent Application Publication
(10) Pub. No.: US 2012/0280214 A1
(43) Pub. Date: Nov. 8, 2012

(54) ORGANIC EL ELEMENT HAVING CATHODE BUFFER LAYER

(75) Inventors: Ryohei Makino, Matsumoto (JP); Chong Li, Matsumoto (JP); Takashi Fukuchi, Matsumoto (JP)

(73) Assignee: FUJI ELECTRIC HOLDINGS CO., LTD.

(21) Appl. No.: 12/734,549

(22) PCT Filed: Dec. 25, 2008
(86) PCT No.: PCT/JP2008/073638

§ 371 Date: Mar. 16, 2011

(51) Int. Cl. H01L 51/54

(52) U.S. Cl. 257/40; 257/E51.026

(57) ABSTRACT

An organic EL element having at least a cathode, a cathode buffer layer comprising a HAT derivative, an electron injection transport layer and a light-emitting layer in that order from a substrate side. The organic EL element of the present invention provides the particular advantages of (1) preventing damage to the electron injection transport performance of the electron injection transport layer due to oxygen and/or moisture adsorbed on the cathode, thereby ensuring a supply of electrons to the light-emitting layer, (2) reducing the drive voltage of the organic EL element, (3) preventing an increase in the drive voltage to provide the same current density over the course of the drive time, and (4) controlling the occurrence of current leaks and pixel defects, thereby improving the quality and manufacturing yield of the organic EL element.

### BACKGROUND OF THE INVENTION

1. Field of the Invention

The present invention relates to an organic EL element applicable to flat panel displays and light sources for illumination. In particular, it is aimed at providing, with high yield, an energy efficient organic EL element that operates at low drive voltages.

2. Description of the Related Art

In recent years, there has been active research into practical application of organic electroluminescence elements (hereunder called organic EL elements). Organic EL elements are expected to provide high luminescent brightness and luminescent efficiency because they can achieve high current densities with low voltage.

Such an organic EL element comprises an organic EL layer sandwiched between two electrodes, and the electrode on the side to be lighted must be highly transmissive. A transparent conductive oxide (TCO) material (such as indium-tin oxide (ITO), indium-zinc oxide (IZO), indium-tungsten oxide (IWO) or the like) is ordinary used as the material of such an electrode. Because these materials have a relatively large work function of about 5 eV, they are commonly used in forming electrodes (anodes) for injection and transport of positive holes into organic materials. However, TCO materials are sometimes used to form electron injection and transport electrodes (cathodes).

The light emission of an organic EL element is obtained as a release of light that accompanies relaxation of the excitation energy of excitons generated by positive holes injected into the lowest unoccupied molecular orbit (LUMO) and electrons injected into the highest occupied molecular orbit (HOMO) of the material of the light-emitting layer of the organic EL layer. In general, organic EL layers having a laminated structure comprising one or more charge transport layers are used to achieve efficient electron injection transport and hole injection transport into the light-emitting layer. Charge transport layers that can be used include hole injection transport layers, hole transport layers, electron transport layers, electron injection layers and the like.

Recently, in documents such as Japanese Patent Application Laid-open No. H4-297076 (Patent Document 1); Japanese Patent Application Laid-open No. H11-251067 (Patent Document 2); Japanese Translation of PCT Application No. 2004-514257 (Patent Document 3); M. Pfeiffer et al., Organic Electronics, 4 (2003), 89-103 (Non-Patent Document 1); and Junji Kido et al., Applied Physics Letters, 73(20), 2866-2868 (1998) (Non-Patent Document 2), techniques have been proposed for doping impurities into the charge transport layer of an organic EL layer having such a laminated structure with the aim of further increasing the energy efficiency of the organic EL element. Japanese Translation of PCT Application No. 2003-519432 (Patent Document 4) proposes using an organic compound having p-type semiconductor properties (hexaazatriphenylene (HAT)) to form a hole injection transport layer or hole transport layer (see Patent Document 4).

The aim of impurity doping is to reduce the drive voltage of the organic EL element by improving the effective mobility of the charge in the charge transport layer and/or reducing the barrier to charge injection into the charge transport layer from the electrode. This technique is similar to the technique of p-type doping and n-type doping in inorganic semiconductors. In the case of a hole injection transport layer or hole transport layer, it is possible to reduce the barrier to hole injection from the electrode (difference between the work function of the anode and the HOMO level of the adjacent hole transport material) and/or improve the effective mobility of the holes in the hole transport material by mixing a material with strong electron accepting properties (acceptor) as an impurity in the hole transport material constituting these layers. In the case of an electron injection layer or electron transport layer, it is possible to reduce the barrier to electron injection from the electrode (difference between the work function of the cathode and the LUMO level of the adjacent electron transport material) and/or increase the effective mobility of the electrons in the electron transport material by mixing a material with strong electron-donating properties (donor) as an impurity in the electron transport material.

Carrier doping of the charge transport layer is a way of improving the effective mobility of the charge (holes or electrons) and lowering the bulk resistance itself. This effect allows the charge transport layer to be made thicker without increasing in the drive voltage of the organic EL element. Increasing the thickness of the charge transport layer is an effective means of controlling element defects due to anode-cathode short circuits caused by particles adhering to the substrate. In the case of flat panel displays in particular, pixel defects, line defects and the like caused by anode-cathode short circuits can be effectively controlled, and the production yield of the displays can be increased.

However, the low-work-function alkali metals such as Li that are commonly used as donor impurities for doping electron injection transport layers have the drawback of being unstable with respect to oxygen and moisture. It is known that the electron transport materials used in electron injection transport layers are also commonly unstable with respect to oxygen and moisture, and that the electron injection transport ability of many electron transport materials is adversely affected by exposure to oxygen or moisture.

When forming an organic EL element having at least a cathode, an electron injection transport layer and a light-emitting layer in that order beginning from the substrate, an electron injection transport layer doped with a donor impurity as described above is formed directly on the cathode formed on the substrate. In this case, the electron transport material and/or donor impurities in the electron injection transport layer are affected by oxygen and/or moisture adsorbed on the surface of the cathode, leading to such problems as (1) failure to obtain initial electron injection transport performance, (2) inhibition of electron transport to the light-emitting layer, (3) elevated drive voltage, and (4) increased drive voltage to provide the same current density over the course of the drive time.

In particular, organic EL elements having cathodes formed using TCO materials are highly liable to these kinds of issues because oxygen and/or moisture is often adsorbed by the cathode surface during the process of forming the TCO material, in the shipping environment before formation of the electron injection transport layer, and during the process of surface treating the cathode.

### SUMMARY OF THE INVENTION

The present invention provides an organic EL element, comprising: a substrate; a cathode that is in direct contact with the substrate; an anode; and an organic EL layer that is sandwiched between the cathode and the anode, that is in direct contact with the cathode, and that comprises a cathode buffer layer, comprising: an organic acceptor substance; an electron injection transport layer; and a light-emitting layer in that order, and wherein the organic acceptor substance comprises a hexaazatriphenylene derivative (a HAT derivative) represented by Chemical Formula (1):

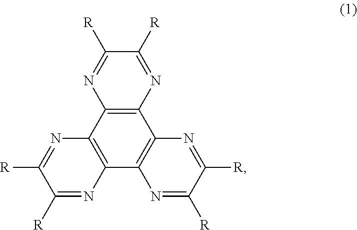

where each R is independently selected from the group consisting of a hydrogen atom, a C₁₋₁₀ hydrocarbon group, a halogen, an alkoxy group, an arylamino group, an ester group, an amide group, an aromatic hydrocarbon group, a heterocyclic group, a nitro group or a nitrile (—CN) group.

The organic acceptor substance may comprise hexaazatriphenylene hexacarbonitrile represented by Chemical Formula (2):

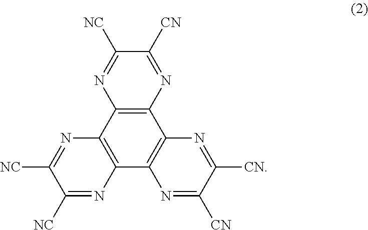

The electron injection transport layer may contain a donor impurity. The cathode may also contain a layer comprised of a transparent oxide conductive film material.

The organic EL element of the present invention has at least a cathode, a cathode buffer layer comprising the HAT derivative, an electron injection transport layer and a light-emitting layer in that order from a substrate side, and thereby provides the particular advantages of preventing damage to the electron injection transport performance of the electron injection transport layer due to oxygen and/or moisture adsorbed on the cathode, thereby ensuring a supply of electrons to the light-emitting layer, reducing the drive voltage of the organic EL element, and preventing an increase in the drive voltage to provide the same current density over the course of the drive time. Because the thickness of the organic EL layer can be increased by the thickness of the cathode buffer layer without any increase in voltage, it is possible to control the occurrence of current leaks and pixel defects, and improve the quality and manufacturing yield of the organic EL element.

### BRIEF DESCRIPTION OF THE DRAWINGS

FIG. 1 is a diagram showing the organic EL element of the present invention; and

FIG. 2 is a graph showing the current-voltage characteristics of organic EL elements of the examples and the comparative example.

### DETAILED DESCRIPTION OF THE INVENTION

The organic EL element of the present invention comprises a substrate, a cathode, an anode, and an organic EL layer sandwiched between the cathode and the anode, wherein the cathode is in direct contact with the substrate, and the organic EL layer, which is in direct contact with the cathode, comprises a cathode buffer layer comprising an organic acceptor substance, an electron injection transport layer and a light-emitting layer in that order, and the organic acceptor substance comprises the hexaazatriphenylene (HAT) derivative represented by Chemical Formula (1):

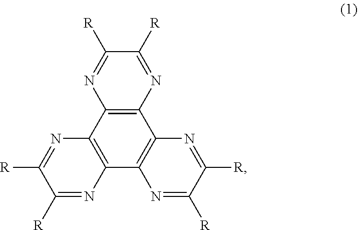

wherein each R is independently selected from the group consisting of a hydrogen atom, C₁₋₁₀ hydrocarbon group, halogen, alkoxy group, arylamino group, ester group, amide group, aromatic hydrocarbon group, heterocyclic group, nitro group or nitrile (—CN) group.

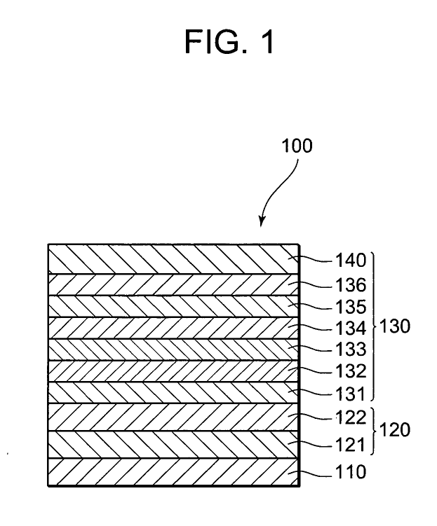

One example of the configuration of the organic EL element of the present invention is shown in FIG. 1. In the organic EL element 100 of FIG. 1, cathode 120, organic EL layer 130 and anode 140 are stacked on substrate 110, and organic EL layer 130 comprises cathode buffer layer 131, electron injection transport layer 132, light-emitting layer 133, hole transport layer 134, hole injection transport layer 135 and anode buffer layer 136 in that order beginning from cathode 120. Hole transport layer 134, hole injection transport layer 135 and anode buffer layer 136 are optional layers that can be selected as desired. In the example given in FIG. 1, cathode 120 comprises reflective layer 121 and transparent layer 122.

The layered structure of organic EL layer 130 is not particularly limited as long as it meets the conditions of having cathode buffer layer 131 in direct contact with cathode 120, and electron injection transport layer 132 and light-emitting layer 133 stacked in that order on cathode buffer layer 131. Optionally, an electron transport layer may also be provided between electron injection transport layer 132 and light-emitting layer 133. For example, one of the following configurations may be adopted:

(1) Cathode buffer layer/electron injection transport layer/light-emitting layer

(2) Cathode buffer layer/electron injection transport layer/light-emitting layer/hole injection transport layer

(3) Cathode buffer layer/electron injection transport layer/electron transport layer/light-emitting layer/hole injection transport layer

(4) Cathode buffer layer/electron injection transport layer/light-emitting layer/hole transport layer/hole injection transport layer

(5) Cathode buffer layer/electron injection transport layer/electron transport layer/light-emitting layer/hole transport layer/hole injection transport layer (in all these configurations, the cathode buffer layer 131 at left is in direct contact with cathode 120, and the rightmost layer is in direct contact with anode 140).

At least one of cathode 120 and anode 140 must be light-transmitting so that luminescence from organic EL layer 130 (light-emitting layer 133) can be provided to the outside. Both cathode 120 and anode 140 may be light-transmitting. Either cathode 120 or anode 140 can be selected as the light-transmitting layer depending on the target application.

Each of the layers is explained in detail below.

Substrate 110—

A glass substrate can normally be used for substrate 110. Alternatively, substrate 110 can be formed from a polymer material such as polyamide; polycarbonate; polyethylene terephthalate, polyethylene naphthalate, polybutylene terephthalate, poly-1,4-cyclohexane dimethylene terephthalate, polyethylene-1,2-diphenoxyethane-4,4′-dicarboxylate, polybutylene terephthalate or another polyester resin; polystyrene; polyethylene, polypropylene, polymethylpentene or another polyolefin; polymethyl methacrylate or another acrylate resin; polysulphone; polyether sulphone; polyether ketone; polyether imide; polyoxyethylene; norbornene resin or the like. When using a polymer material, substrate 110 may be rigid or flexible. Alternatively, when the luminescence of organic EL layer 130 is not provided to the outside through substrate 110, substrate 110 may be formed using an optically opaque material such as a silicon or other semiconductor or a ceramic.

Cathode 120—

Cathode 120 may be either light-reflecting or light-transmitting with the condition that either cathode 120 or anode 140 must be light-transmitting.

To make cathode 120 light-reflecting, as shown in FIG. 1, cathode 120 may be composed of reflective layer 121 and transparent layer 122. In this case, it is preferable to adopt a configuration in which reflective layer 121 is in contact with substrate 110 and transparent layer 122 is in contact with organic EL layer 130. Reflective layer 121 can be formed using a high-reflectance metal, a high-reflectance amorphous alloy or a high-reflectance microcrystalline alloy. Examples of high-reflectance metals include Al, Ag, Ta, Zn, Mo, W, Ni, Cr or the like. Examples of high-reflectance amorphous alloys include NiP, NiB, CrP, CrB or the like. Examples of high-reflectance microcrystalline alloys include NiAl, silver alloys or the like. Transparent layer 122 can be formed using a TCO material such as ITO, IZO, IWO, AZO (Al-doped zinc oxide) or the like.

To make cathode 120 light-transmitting, on the other hand, cathode 120 can be composed of a light-transmitting layer and a charge-injecting metal layer. In this case, in order to achieve smooth electron injection into organic EL layer 130, the light-transmitting layer should preferably be in contact with substrate 110, and the electron-injecting metal layer should be in contact with organic EL layer 130. The light-transmitting layer can be formed using the TCO materials mentioned above. The electron-injecting metal layer can be formed using metals, alloys and electrically conductive compounds having small work functions (4.0 eV or less) and mixtures of these. Specific examples of materials that can be used include sodium, sodium-potassium alloys, magnesium, lithium, magnesium-silver alloys, aluminum/aluminum oxide, aluminum-lithium alloys, indium, rare earth metals and the like.

Alternatively, cathode 120 can be formed from only the aforementioned electron-injecting metal layer or only the light-transmitting layer.

Cathode 120 can be prepared by forming a thin film of one of these materials using any method known in the field, such as vapor deposition, sputtering or the like.

Cathode Buffer Layer 131—

Cathode buffer layer 131 is the outermost layer on the cathode side of organic EL layer 130, and is in contact with cathode 120 and electron injection transport layer 132. The cathode buffer layer is formed from the HAT derivative represented by Chemical Formula (1):

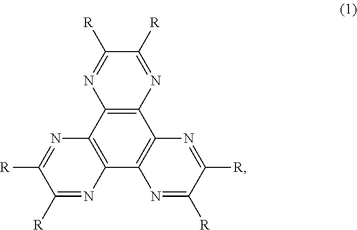

wherein R is as defined previously.

More preferably, cathode buffer layer 131 is formed from the hexaazatriphenylene hexacarbonitrile (HAT-CN) represented by Chemical Formula (2):

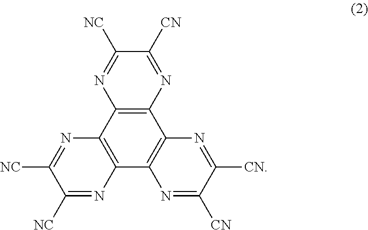

Cathode buffer layer 131 has a film thickness of 5 to 200 nm.

Because the HAT derivative represented by Chemical Formula (1) has strong electron-accepting properties and a deep LUMO, no electron injection barrier forms between cathode 131 and cathode buffer layer 131 formed from the HAT derivative. Consequently, electrons can be withdrawn from cathode 120 and transported towards electron injection transport layer 132 with little or no voltage drop. Moreover, because the bulk conductivity of the HAT derivative is greater than or equal to that of conventionally used charge transport materials, the bulk voltage drop (voltage drop when electrons pass through cathode buffer layer 131) can be kept extremely low. The HAT derivative is also stable with respect to oxygen and moisture, reducing the likelihood that the electron injection and transport properties will be adversely affected by exposure to oxygen and/or moisture.

The crystallinity of the HAT derivative after film formation is higher than that of ordinary amorphous organic materials. The high crystallinity of the HAT derivative has the effect of blocking oxygen and moisture adsorbed on the lower layer (that is, cathode 120) from passing through to the layer formed on top (that is, electron injection transport layer 132).

When electron injection transport layer 132 is doped with a donor impurity, moreover, electrons can be moved from cathode buffer layer 131 to electron injection transport layer 132 with very little voltage drop.

Because of the features described above, it is possible to form an energy-efficient organic EL element that provides high current densities at a low drive voltage. Because it is also possible to (1) prevent a drop in charge transport performance due to oxygen and moisture adsorbed on the surface of cathode 120, and (2) increase the thickness of organic EL layer 130 by the thickness of cathode buffer layer 131 without increasing the drive voltage, pixel defects and line defects due to short circuits between cathode 120 and anode 140 can also be prevented, thereby improving the quality and manufacturing yield of the organic EL element.

Electron Injection Transport Layer 132—

Electron injection transport layer 132 is a layer positioned between cathode buffer layer 131 and light-emitting layer 133. Electron injection transport layer 132 can be formed from an oxadiazole derivative such as 2-(4-biphenylyl)-5-(4-t-butylphenyl)-1,3,4-oxadiazole (PBD) or 1,3,5-tris(4-t-butylphenyl-1,3,4-oxadiazolyl)benzene (TPOB); a triazole derivative such as 3-phenyl-4-(1′-naphthyl)-5-phenyl-1,2,4-triazole (TAZ); a triazine derivative; a phenylquinoxaline; a thiophene derivative such as 5,5′-bis(dimesitylboryl)-2,2′-bithiophene (BMB-2T) or 5,5′-bis(dimesitylboryl)-2,2′:5′2′-terthiophene (BMB-3T); or an aluminum complex such as aluminum tris(8-quinolinolate) (Alq₃) or another electron injecting transport material.

Alternatively, electron injecting transport layer 132 can be formed by doping a host material with a donor impurity such as Li, Na, K, Cs or another alkali metal, LiF, NaF, KF, CsF or another alkali metal halide, or Cs₂CO₃ or another alkali metal carbonate or the like. The electron injection transport materials described above can be used as the host material. Doping with a donor impurity serves to promote movement of electrons from cathode buffer layer 131.

Electron Transport Layer—

The electron transport layer (not shown) is an optional layer that can be provided between electron injection transport layer 132 and light-emitting layer 133 in order to adjust the amount of electrons supplied to light-emitting layer 133. The electron transport layer can be formed using the electron injection transport materials described above. In particular, if electron injection transport layer 132 is doped with a donor impurity, quenching and other adverse effects from dispersion of donor impurities into light-emitting layer 133 can be avoided by not doping the electron transport layer with impurities. In this case, the electron transport layer can be formed from the same material as the host material as electron injection transport layer 132.

Light-Emitting Layer 133—

Light-emitting layer 133 is the layer in which electrons injected from cathode 120 and holes injected from anode 140 are recombined to produce light. The material of light-emitting layer 133 can be selected according to the desired hue of the luminescence. For example, light-emitting layer 133 can be formed using a benzothiazole, benzoimidazole, benzoxazole or other fluorescent brightener or a styrylbenzene compound, aromatic dimethylidine compound or the like in order to obtain blue to blue-green luminescence. Light-emitting layer 133 can also be formed by adding a dopant to one of these materials as the host material. Examples of materials than can be used as dopants include perylene (blue), which is also used as a laser pigment.

Hole Injection Transport Layer 135—

Hole injection transport layer 135 in the present invention is an optional layer provided for purposes of promoting supply of holes to light-emitting layer 133. Hole injection transport layer 135 can be formed using hole injection transport materials commonly used in organic EL elements, or p-type organic semiconductor materials used in organic TFTs. Examples of hole injection transport materials that can be used include 4,4′-bis{N-(1-naphthyl)-N-phenylamino}biphenyl (NPB), 2,2′,7,7′-tetrakis(N,N-diphenylamino)-9,9′-spirobifluorene (Spiro-TAD), tri(p-terphenyl-4-yl)amine (p-TTA), 1,3,5-tris[4-(3-methylphenylphenylamino)phenyl]benzene (m-MTDAPB), 4,4′,4″-tris(N-carbazolyl)-triphenylamine (TCTA) and the like. Examples of p-type organic semiconductor materials that can be used include pentacene, napthacene, α,ω-dihexyl-6-thiophene and the like.

Alternatively, hole injection transport layer 135 can be formed by doping a host material with an acceptor impurity such as tetrafluorotetracyano-quinodimethane (F₄-TCNQ), FeCl₃, MoO₃, V₂O₅ or the like. The hole injection transport materials mentioned above can be used for the host material. Doping with an acceptor impurity serves to promote movement of positive holes from cathode 140 or cathode buffer layer 136.

Hole Transport Layer 134—

Hole transport layer 134 is an optional layer that may be provided between hole injection transport layer 135 and light-emitting layer 133 for purposes of adjusting the amount of holes supplied to light-emitting layer 133. Hole injection layer 134 may be formed using any material known to be used for the hole injection transport materials of organic EL elements or the p-type organic semiconductor materials of organic TFTs, such as a material having a partial triarylamine structure, partial carbazole structure or partial oxadiazole structure. From the standpoint of hole injectability into light-emitting layer 133, the HOMO level of the material forming hole transport layer 134 should preferably be close to the HOMO level of the material forming light-emitting layer 133. Specifically, hole transport layer 134 can be formed using the hole injection transport materials and p-type organic semiconductor materials used to form hole injection transport layer 135 above, especially NPB, spiro-TAD, p-TTA, TCTA or the like. When hole injection transport layer 135 is doped with an acceptor impurity in particular, quenching and other adverse effects from dispersion of acceptor impurities into light-emitting layer 133 can be avoided by not doping the hole transport layer 134 with impurities. In this case, the hole transport layer can be formed from the same material as the host material of hole injection transport layer 135.

Anode Buffer Layer 136—

Anode buffer layer 136 is an optional layer that can be provided in order to mitigate damage to hole injection transport layer 135 and lower layers during formation of anode 140. Anode buffer layer 136 can be formed using a material such as MgAg, MoO₃ or the like.

Each of the aforementioned layers making up organic EL layer 130 can be formed by any means known in the field, such as vacuum deposition (resistance heating or electron beam heating) or the like.

Anode 140—

Anode 140 may be either light-reflecting or light-transmitting as long as either cathode 120 or anode 140 is light-transmitting.

When anode 140 is light-transmitting, the anode 140 can be formed from the aforementioned TCO materials. A laminate of a TCO material layer with a metal material thin film (about 50 nm thick or less) can be used for anode 140 with the aim of reducing the electrical resistance of anode 140 and/or controlling the light reflectance and light transmittance of anode 140. Alternatively, an auxiliary electrode (not shown) can be provided parallel to an anode 140 composed of a TCO material and connected to the anode 140 with the aim of reducing the electrical resistance of anode 140. This auxiliary electrode can be formed of a low-resistance electrical material. When an auxiliary electrode is included, it is preferably disposed in an area other than the outgoing pathway of light emission from organic EL layer 130.

When anode 140 is light-reflecting, a laminate of a reflecting layer and a transparent layer of a TCO material can be used for anode 140. In this case, the transparent layer is preferably in contact with organic EL layer 130, while the reflecting layer is in contact with the transparent layer on the opposite side from organic EL layer 130. The reflecting layer is preferably formed using a material such as those used for reflecting layer 121 of cathode 120.

Anode 140 can be prepared by forming a thin film of the aforementioned material using any means known in the field, such as deposition, sputtering or the like.

### EXAMPLES

The present invention is explained in more detail below using examples.

### Example 1

This example is an example of an organic EL element having cathode 120 made of Ag and IZO, cathode buffer layer 131, electron injection transport layer 132, light-emitting layer 133, hole transport layer 134, hole injection transport layer 135, anode buffer layer 136 and anode 140 formed in that order on substrate 110.

An Ag film 100 nm thick was formed by DC magnetron sputtering on glass substrate 110 (length 50 mm×width 50 mm×thickness 0.7 mm; Corning 1737 glass). An IZO film 110 nm thick was then formed by DC magnetron sputtering (target: In₂O₃+10 wt % ZnO, discharge gas: Ar+0.5% O₂ discharge pressure: 0.3 Pa, discharge power: 1.45 W/cm², substrate transport rate 162 mm/min) on the upper surface of the Ag film. Next, the laminate of Ag film and IZO film was worked in 2 mm-wide stripes by photolithography to form reflecting layer 121 having a width of 2 mm and transmitting layer 122 having a width of 2 mm, to obtain cathode 120.

Organic EL layer 130 was then formed by resistance heating deposition on cathode 120. HAT-CN was first deposited up to a thickness of 20 nm to form cathode buffer layer 131. Next, tris(8-hydroxyquinolinate)aluminum (Alq₃) and Li were co-deposited so as to obtain an equal mole ratio of Alq₃ and Li and form electron injection transport layer 132 with a thickness of 10 nm. The molar amounts of Alq₃ and Li in electron injection transport layer 132 were equal. Next, 4,4′-bis(diphenylvinyl)biphenyl (DPVBi) and 4,4′-bis[2-{4-(N,N-diphenylamino)phenyl}vinyl]biphenyl (DPAVBi) were co-deposited to form light-emitting layer 133 with a thickness of 35 nm. The film thickness ratio of DPVBi and DPAVBi was 100:3. Next, NPB was deposited to form hole transport layer 134 with a thickness of 10 nm. Next, [4,4′,4″-tris(3-methylphenylphenylamino)-triphenylamine (m-MTDATA) and F₄-TCNQ were co-deposited to form hole injection transport layer 135 with a thickness of 60 nm.

The film thickness ratio of m-MTDATA and F₄-TCNQ was 100:3. Finally, molybdenum trioxide (MoO₃) was deposited to form anode buffer layer 136 with a thickness of 40 nm. Formation of the constituent layers of organic EL layer 130 was accomplished in one process without any break in vacuum.

Next, the laminate comprising the formed organic EL layer 130 was transferred to a facing target sputtering apparatus without any break in vacuum.

Next, IZO was deposited through a metal mask to form cathode 140 as a stripe 200 nm thick and 2 mm wide and obtain organic EL element 100. The long direction of the stripe of cathode 140 was set perpendicular to the long direction of the stripe of anode 120.

Finally, organic EL element 100 was transferred to a plasma CVD unit without any break in vacuum. Next, SiO₂N_{0.3} was deposited by plasma CVD to form a passivation layer (not shown) 3000 nm thick so as to cover organic EL layer 100. The internal pressure of the unit (that is, the gas pressure) was 100 Pa, and RF power was applied with a frequency of 13.56 MHz and an output of 0.6 kW as the plasma generating power to deposit SiO₂N_{0.3} at a rate of 300 nm/min.

### Example 2

An organic EL element was produced by following the procedures used in Example 1, except that the thickness of cathode buffer layer 131 was changed to 50 nm.

### Comparative Example

An organic EL element was produced by following the procedures used in Example 1 except that no cathode buffer layer 131 was formed.

### EVALUATION

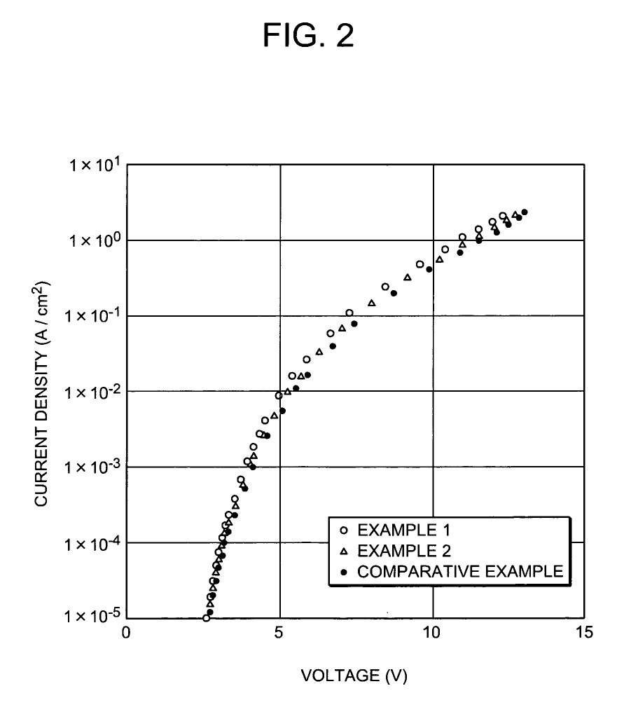

The current-voltage characteristics of the resulting organic EL elements are shown in FIG. 2. FIG. 2 shows that the voltages of the organic EL elements of Examples 1 and 2 of the present invention having HAT-CN cathode buffer layers were lower than the voltage of the element of the Comparative Example having no cathode buffer layer. For example, comparing the voltage required to yield a current density of 0.01 A/cm², the voltage of the element of Example 1 was 0.5 V lower than the voltage of the element of the Comparative Example. The voltage of the element of Example 2, which had a thicker cathode buffer layer than in Example 1, was 0.2 V higher than the voltage of the element of Example 1 but 0.3 V lower than the voltage of the element of the Comparative Example.

The organic EL elements of Examples 1 and 2 and the Comparative Example were then driven continuously for 800 hours at a current density of 0.04 A/cm². In the Comparative Example, the voltage to give a current density of 0.01 A/cm² after continuous driving was 0.8 V higher than the initial voltage. By contrast, the rise in voltage after continuous driving was only 0.3 V in the case of the elements of Examples 1 and 2.

As discussed above, with the organic EL elements of Examples 1 and 2 of the present invention it was possible to reduce the drive voltage and prevent an increase in the drive voltage to give the same current density after a certain driving time. Because the thickness of the organic EL layer is increased by the thickness of the cathode buffer layer without any increase in voltage, it is also possible to control current leaks and pixel defects. Consequently, it should also be possible to increase the quality and manufacturing yield of the organic EL element.

1. An organic EL element, comprising:
a substrate;
a cathode that is in direct contact with the substrate;
an anode; and
an organic EL layer that is sandwiched between the cathode and the anode, that is in direct contact with the cathode, and that comprises a cathode buffer layer, comprising:
an organic acceptor substance;
an electron injection transport layer; and
a light-emitting layer in that order, and
wherein the organic acceptor substance comprises a hexaazatriphenylene derivative represented by Chemical Formula (1): 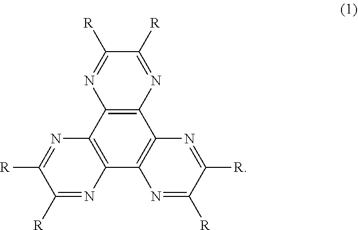
where each R is independently selected from the group consisting of a hydrogen atom, a C₁₋₁₀ hydrocarbon group, a halogen, an alkoxy group, an arylamino group, an ester group, an amide group, an aromatic hydrocarbon group, a heterocyclic group, a nitro group or a nitrile (—CN) group.

2. The organic EL element according to claim 1, wherein the organic acceptor substance comprises hexaazatriphenylene hexacarbonitrile represented by Chemical Formula (2):

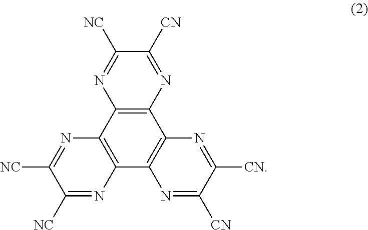

3. The organic EL element according to claim 1, wherein the electron injection transport layer contains a donor impurity.

4. The organic EL element according to claim 1, wherein the cathode contains a layer comprised of a transparent electrically conductive oxide material.
